(19) United States
(12) Patent Application Publication
(10) Pub. No.: US 2003/0066483 A1
(43) Pub. Date: Apr. 10, 2003

(54) Atomic layer deposition apparatus and method for operating the same

(75) Inventors: Joo-Won Lee, Suwon-City (KR); Yeong-Kwan Kim, Suwon-City (KR); Jae-Eun Park, Yongin-City (KR)

Correspondence Address: F. Chau & Associates, LLP, Suite 501, 1900 Hempstead Turnpike, East Meadow, NY, 11554, US

(73) Assignee: Samsung Electronics Co., Inc.

(21) Appl. No.: 10/253,689

(22) Filed: Sep. 25, 2002

(30) Foreign Application Priority Data
Oct. 5, 2001 (KR) 2001-61450

(51) Int. Cl. C23C 16/00; H01L 21/31

(52) U.S. Cl. 118/715; 438/758

(57) ABSTRACT

An atomic layer deposition apparatus and a method of operating the same are provided. The atomic layer deposition apparatus is used to deposit an atomic layer by repeatedly supplying and purging a process gas, and includes a chamber used for depositing an atomic layer, a gas injection hole through which the process gas is supplied to the chamber, a first outlet through which particles or remnants are removed from the chamber when supplying the process gas, and a second outlet through which exhaust gas is discharged from the chamber when purging the process gas.

### PRIORITY

This application claims priority to an application entitled “ATOMIC LAYER DEPOSITION APPARATUS AND METHOD FOR OPERATING SAME” filed in the Korean Industrial Property Office on Oct. 5, 2001 and assigned Serial No. 2001-61450, the contents of which are hereby incorporated by reference.

### BACKGROUND OF THE INVENTION

1. Field of the Invention

The present invention relates to an apparatus for manufacturing semiconductor devices and a method of operating the apparatus, and more particularly, to an atomic layer deposition (hereinafter, “ALD”) apparatus used for manufacturing semiconductor devices and a method of operating the ALD apparatus.

2. Description of the Related Art

In general, an atomic layer deposition (ALD) method is used to deposit thin layers in manufacturing semiconductor devices. In the ALD method, at least two process gases are sequentially and repeatedly supplied, at different times so that they are not mixed together, until a thin film is obtained. As a result, a thin film is deposited only with a substance that is absorbed by a surface of a substrate, e.g., chemical molecules including components constituting the thin film. Since an amount of the substance absorbed on the surface is self-limited, the thin film is formed evenly throughout the substrate, independent of the amount of process gases supplied to the atmosphere. For this reason, it is possible to form a thin layer evenly on a surface having a very high aspect ratio to a predetermined thickness, and further, it is easy to adjust the thickness of an ultra-thin film that is measured in nanometer units. Since the thickness of a layer deposited in each period of supplying a process gas is regular, it is possible to adjust and estimate the thickness of the layer by the number of periods. To deposit an atomic layer, process gases supplied must not be mixed together, and thus, a first process gas is supplied and purged before a second process gas is supplied.

Hereinafter, a general ALD apparatus will be described with reference to FIG. 1. Referring to FIG. 1, a holder 14 on which a semiconductor wafer 12 is placed is installed in a chamber 10 for depositing an atomic layer. The holder 14 has a driving unit 15 located on the bottom, which moves upward and downward. The chamber 10 has an injection hole 16 located on the top through which a process gas is injected. The injection hole 16 is connected to a showerhead 20 having spraying holes 20a that are used in spraying a process gas, which is injected through the injection hole 16, onto a surface of the semiconductor wafer 12. At a lower portion of a sidewall of the chamber 10 is formed an outlet 18 that exhausts a process gas that is to be exhausted. Here, reference numerals 19 and 22 denote a valve for opening/shutting the outlet 18 and the inside part of the chamber 10, i.e., a chamber space, respectively.

In the operation of the general ALD apparatus, a first process gas is supplied through the injection hole 16 for a predetermined time. To increase deposition efficiency, a maximum amount of the first process gas and the diameter of the outlet 18 must be minimized. At this time, the outlet 18 is preferably shut but may be left open to discharge unnecessary particles or remnants (not shown) remaining in the chamber space 22.

Next, the supply of the first process gas is discontinued, and the first process gas supplied is purged. At this time, exhaust gases are discharged via the outlet 18 by opening the valve 19.

Thereafter, a second process gas is supplied through the injection hole 16 and is then purged as described above.

However, the general ALD apparatus has some problems. In detail, to increase the deposition efficiency, the outlet 18 must be opened at only a minimum diameter when a process gas is supplied and must be opened to a maximum diameter when the process gas is purged. However, according to the operating mechanism of the valve 19, it takes at least 2-3 seconds to open or shut the valve 19, which hinders a smooth process. Also, after purging the first process gas, the valve 19 of the outlet 18 must be completely shut before supplying the second process gas through the injection hole 16. At this time, fluid turbulence may occur around the valve 19 due to the abrupt shutting of the valve 19, which makes it difficult to deposit a clean thin film.

### SUMMARY OF THE INVENTION

To overcome the above problems, it is an objective of the present invention to provide an atomic layer deposition apparatus in which a process gas can be supplied and purged smoothly.

It is another objective of the present invention to provide an atomic layer deposition apparatus in which fluid turbulence is minimized or eliminated.

It is a further objective of the present invention to provide a method of operating an atomic layer deposition apparatus in accordance with the present invention.

Accordingly, to achieve one aspect of the above and other objectives, there is provided an atomic layer deposition apparatus in which a process gas is repeatedly supplied and purged to deposit an atomic layer, the apparatus including a chamber used for depositing an atomic layer; a gas injection hole through which a process gas is supplied to the chamber; a first outlet through which remnants are removed from the chamber when supplying the process gas; and a second outlet through which exhaust gas is discharged from the chamber when purging the process gas.

Here, the first and second outlets may branch out from one unified line, and an interlocking valve, which controls the continuous opening of one outlet and selective opening of the other outlet, is installed in the one line from which the first and second outlets branch out.

An on/off valve is installed in the first and second outlets, respectively. Also, a mass flow control valve, which controls a flow rate of the exhaust gas, is further installed in the first or second outlet. Here, the on/off valve may be a slit valve and the mass flow control valve may be a pressure control valve, a butterfly valve, or a throttle valve.

The diameter of the second outlet is larger than that of the first outlet, which enables a large amount of exhaust gas to be discharged when purging the process gas.

To achieve another aspect of the above objectives, there is provided a method of operating an atomic layer deposition apparatus that has a gas supply outlet and a purging outlet installed on a wall of a chamber and on/off valves that control the outlets, the method including (a) placing a semiconductor wafer in the chamber; (b) supplying a first process gas to the semiconductor wafer while the gas supply outlet is open and the purging outlet is shut; (c) opening the purging outlet and purging the first process gas; (d) shutting the purging outlet and supplying a second process gas; and (e) opening the purging outlet and performing a purging process on the second process gas.

Here, the gas supply outlet is kept open in steps (c) through (e).

According to another aspect of the present invention, the gas supply outlet and the purging outlet include mass flow control valves that control a flow rate of an exhaust gas, and the mass flow control valves are opened such that a minimum amount of the exhaust gas is discharged in steps (b) and (d).

According to another aspect of the present invention, the gas supply outlet and the purging outlet include mass flow control valves that control a flow rate of an exhaust gas, and the mass flow control valves are completely opened such that a maximum amount of the exhaust gas is discharged in steps (c) and (e).

Further, steps (b) through (e) may be repeated at least once.

In an ALD apparatus according to the present invention, a gas supplying outlet through which particles or remnants are discharged during the supply of a process gas and a purging outlet through which a large amount of exhaust gas is discharged during a purging process are installed in a chamber in which an atomic layer is deposited. Accordingly, it is possible to discharge a minimum amount of exhaust gas during the supply of the gas, and a maximum amount of exhaust gas during the purging process, thereby maximizing the deposition efficiency.

### BRIEF DESCRIPTION OF THE DRAWINGS

The above objectives and advantages of the present invention will become more apparent by describing in detail preferred embodiments thereof with reference to the attached drawings in which:

FIG. 1 is a cross-sectional view of a conventional atomic layer deposition (ALD) apparatus;

FIG. 2 is a cross-sectional view of an ALD apparatus according to a first embodiment of the present invention;

FIG. 3 is a graph showing the supply of gas to an ALD apparatus according to the present invention;

FIG. 4 is a flow chart illustrating a method of operating the ALD apparatus according to the first embodiment of the present invention;

FIG. 5 is a cross-sectional view of an ALD apparatus according to a second embodiment of the present invention;

FIG. 6 is a cross-sectional view of an ALD apparatus according to a third embodiment of the present invention; and

FIG. 7 is a cross-sectional view of an ALD apparatus according to a fourth embodiment of the present invention.

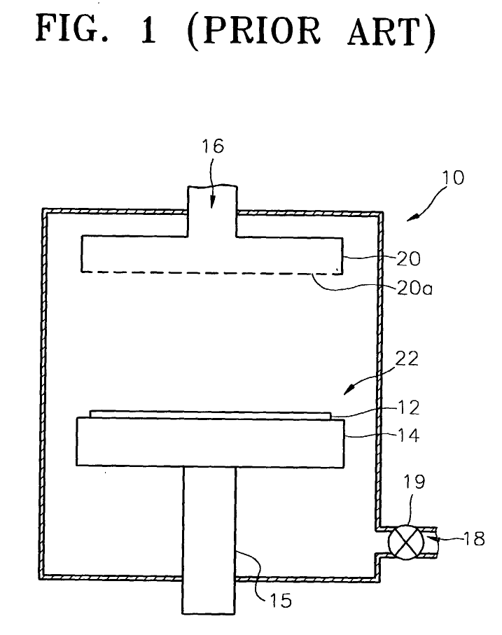

### DETAILED DESCRIPTION OF PREFERRED EMBODIMENTS OF THE INVENTION

The present invention will be described more fully with reference to the accompanying drawings, in which preferred embodiments of the invention are shown. This invention may, however, be embodied in many different forms and should not be construed as being limited to the embodiments set forth herein. Rather, these embodiments are provided so that the disclosure of the present invention will be thorough and complete and will fully convey the concept of the invention to those skilled in the art. In the drawings, the thickness of the layers and regions are exaggerated for clarity. It will also be understood that when a layer is referred to as being “on” another layer or substrate, it can either be directly on the other layer or substrate or have intervening layers. The same reference numerals in different drawings represent the same elements, and thus, their descriptions will be omitted.

First Embodiment

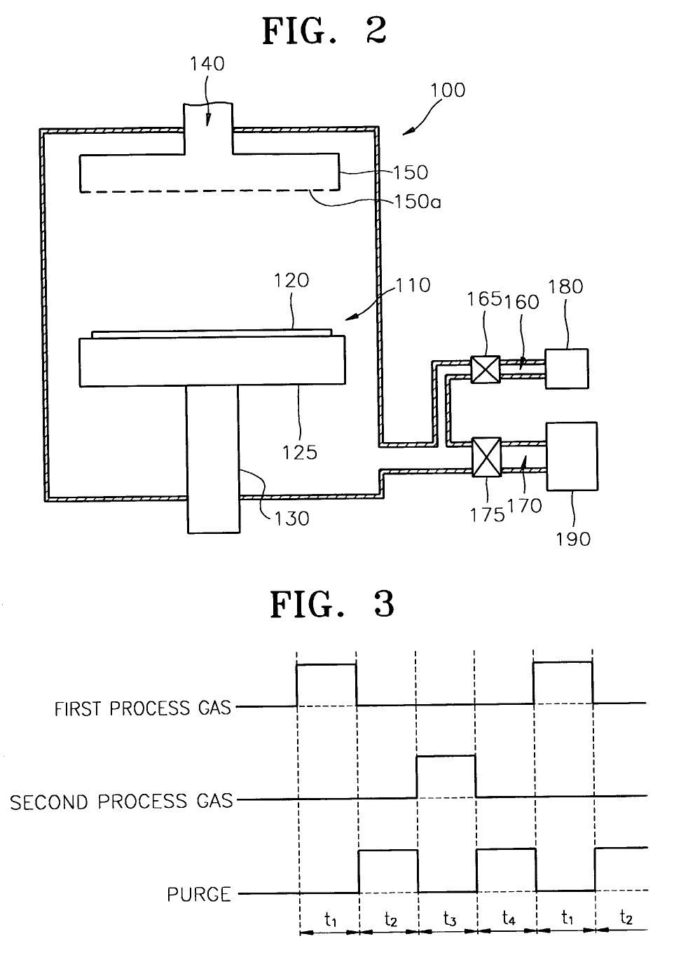

Referring to FIG. 2, a chamber 100, which is used to deposit atomic layers, includes a wall 102 with which a predetermined chamber space 110 is defined. At the bottom of the chamber 100, a holder 125 is installed on which a semiconductor wafer 120, on which atomic layers are to be deposited, is located. The holder 125 moves upward and downward by a driving unit 130 that is positioned at the bottom of the holder 125. At least one gas injection hole 140, through which a process gas is supplied to the chamber space 110, is positioned above the holder 125, and is connected with a gas supply source (not shown). The gas injection hole 140 is also connected with a showerhead 150 that sprays gas toward a surface of the semiconductor wafer 120. The showerhead 150 includes a plurality of spraying holes 150a through which process gas is sprayed. Here, the showerhead 150 may be a multi-step showerhead that supplies reaction gases, which are not mixed together, to the chamber space 110 of the chamber 100.

Also, first and second outlets 160 and 170, which branch out from a point to discharge exhaust gas, are installed at a lower portion of a sidewall of the chamber 100. Here, the first outlet 160 has a comparatively smaller diameter to discharge a minimum amount of particles or remnants during the supply of gas, whereas the second outlet 170 has a comparatively large diameter to discharge a large amount of exhaust gases when purging gas after gas is supplied. On/off valves 165 and 175 are installed at the first and second outlets 160 and 170 and are selectively opened or shut during the supply or purge of the process gas. In this case, a slit valve can be used as the on/off valves 165 and 175. Also, the first and second outlets 160 and 170 are connected to first and second pumps 180 and 190, respectively. The capacity of the first pump 180 connected to the first outlet 160 is smaller than that of the second pump 190 connected to the second outlet 170. This is because the first outlet 160 is used as a passage through which the minimum amount of remnant gas is discharged and thus does not need to be connected to a pump of large capacity, whereas the second outlet 170 is used to purge process gas and thus must be connected to a pump of a large capacity. The first and second outlets 160 and 170 may, however, be connected to the same pump.

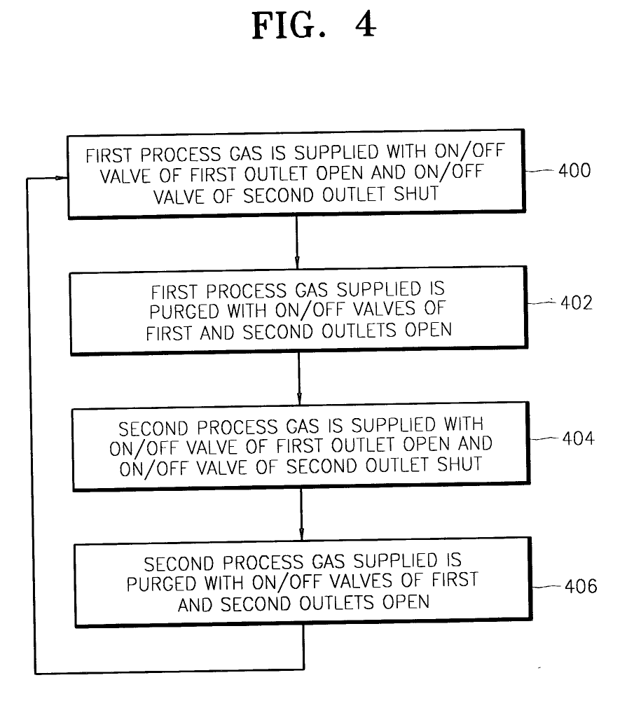

For the operation of the ALD apparatus according to the first embodiment, with reference to FIGS. 3 and 4, the semiconductor wafer 120 is loaded on the holder 125 in the chamber space 110. Then, a first process gas is supplied to the semiconductor wafer 120 for a first time t1, while the on/off valve 165 of the first outlet 160 is opened and the on/off valve 175 of the second outlet 170 is shut (Step 400). Thus, the first process gas is supplied with the first outlet 160, through which the minimum amount of remnant gas is discharged, open. Some of the supplied first process gas is chemically absorbed by a surface of the semiconductor wafer 120, while the remaining first process gas remains in the chamber space 110 or is discharged via the first outlet 160.

After completion of the supply of the first process gas, a purging process is performed for a second time t2 so as to discharge exhaust gas remaining in the chamber space 110 (Step 402). During the purging process, the on/off valve 175 of the second outlet 170 is opened. It is preferable that the on/off valve 165 of the first outlet 160 is kept open as well. By doing this, the purging efficiency becomes greater than that in a conventional ALD apparatus because the second outlet 170 has a comparatively large diameter to discharge a large amount of exhaust gas as described above and further, the purging process is performed with the first and second outlets 160 and 170 open. Here, the purging process may be performed by only opening the first and second outlets 160 and 170 as, described above or by supplying a purging gas, such as nitrogen gas, through the gas injection hole 140.

After purging the first process gas, a second process gas is supplied to the chamber space 110 for a third time t3 so as to deposit an atomic layer. To maximize the efficiency of supplying the second process gas, the on/off valve 165 of the first outlet 160 is opened and the on/off valve 175 of the second outlet 170 is shut (Step 404). Since the first outlet 160 is continuously opened and the second outlet 170 is shut, a fluid turbulence due to the abrupt shutting of an on/off valve can be prevented.

After supplying the second process gas, it is purged for a fourth time t4. During this purging process, the on/off valve 175 of the second outlet 170 is opened, and the on/off valve 165 of the first outlet 160 is open, as in the above purging process of the first process gas (Step 406). As a result, exhaust gas generated in the chamber space 110 due to the supply of the second process gas is discharged.

As described above, atomic layer deposition can be smoothly performed by separately installing an outlet used with the supply of gas and an outlet used with the purging of gas. Fluid turbulence due to the abrupt opening or shutting of an on/off valve hardly occurs because an outlet is kept open and shut only when gas is purged.

Second Embodiment

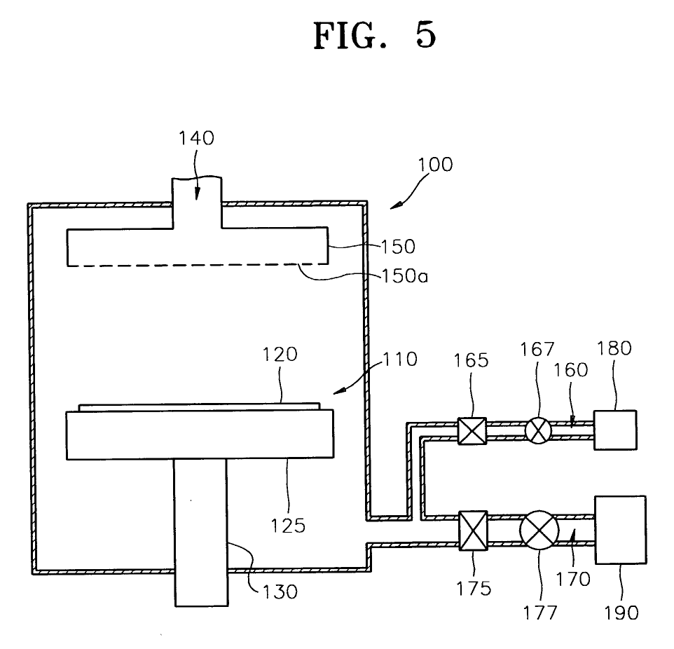

FIG. 5 is a cross-sectional view of an ALD apparatus according to a second embodiment of the present invention. Components that are the same as those in the ALD apparatus according to the first embodiment will be described with the same reference numerals, and their explanations will be omitted.

Referring to FIG. 5, mass flow control valves 167 and 177 are installed on first and second outlets 160 and 170, respectively. However, the number and location of a mass flow control valve is not limited. For instance, a mass flow control valve may be positioned between the respective on/off valves 165 and 175 and the respective pumps 180 and 190 on the outlets 160 and 170. The mass flow control valves 167 and 177 control the displacement of gas when the on/off valves 165 and 175 are opened. Here, the mass flow control valves 167 and 177 may each represent a butterfly valve or throttle valve.

In the operation of the ALD apparatus according to the second embodiment, a semiconductor wafer 120 is loaded on a holder 125 in a chamber space 110. Next, a first process gas is supplied to the semiconductor wafer 120 for a first time t1. At this time, the on/off valve 165 of the first outlet 160 is opened and the on/off valve 175 of the second outlet 170 is shut. The mass flow control valve 167 of the first outlet 160 is slightly opened to discharge small particles or exhaust gas. As a result, the first process gas can be supplied while minimizing the amount of gas to be discharged.

Once the supply of the first process gas is completed, a purging process is performed for a second time t2 to discharge exhaust gas remaining in the chamber space 110. During the purging process, the on/off valve 175 of the second outlet 170 is opened, and the mass flow control valve 177 of the second outlet 170 is opened to a maximum in order to discharge exhaust gas. At this time, it is preferable that the on/off valve 165 of the first outlet 160 is kept open, and the mass flow control valve 167 of the first outlet 160 is controlled to pass at a maximum flow rate. Therefore, a great deal of exhaust gas in the chamber 100 can be discharged rapidly via the outlets 160 and 170 in a short period of time.

After the purging process, a second process gas is supplied to the chamber space 110 for a third time t3 to deposit an atomic layer. To maximize the efficiency of the supply of the second process gas, the on/off valve 175 of the second outlet 170 is shut, whereas the on/off valve 165 of the first outlet 160 is open. Further, the mass flow control valve 167 of the first outlet 160 is opened slightly to discharge the minimum amount of exhaust gas. In this case, while the first outlet 160 is open, only the second outlet 170 is shut, thereby preventing fluid turbulence due to the abrupt shutting of an on/off valve.

After supplying the second process gas, the second process gas is purged for a fourth time t4. At this time, the on/off valve 175 of the second outlet 170 is opened, and the on/off valve 165 of the first outlet 160 is opened, as in the purging process of the first process gas. Also, the mass flow control valves 167 and 177 are opened to the maximum flow rate. Accordingly, exhaust gas remaining in the chamber space 110 can be discharged.

In the ALD apparatus according to the second embodiment, it is possible to precisely control the amount of exhaust gas because mass flow control valves are installed on the respective outlets.

Third Embodiment

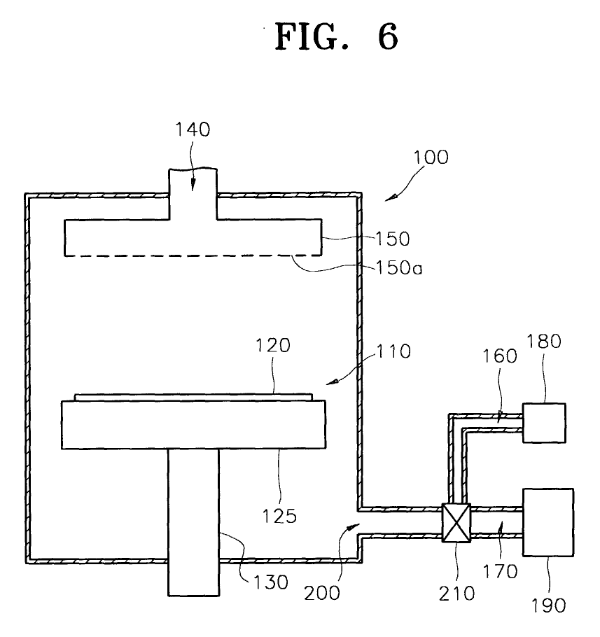

FIG. 6 is a cross-sectional view of an ALD apparatus according to a third embodiment of the present invention. Components that are the same as those in the ALD apparatus according to the first embodiment will be described with the same reference numerals and their explanations will be omitted.

Referring to FIG. 6, first and second outlets 160 and 170 branch out from a unified outlet 200. An interlocking valve 210 is installed near the unified outlet 200 to function as the on/off valves used in the ALD apparatus according to the first embodiment. The interlocking valve 210 is controlled to continuously open one of several valves and selectively open or shut the other valves. The first outlet 160 is opened during the supply of the process gas, and the second outlet 170 is opened by the interlocking valve 210 during a purging process. In an ALD apparatus according to the present invention, the first outlet 160 is open when supplying and purging the process gas, and the second outlet 170 is open only during the purge of process gas. Accordingly, with the interlocking valve 210, it is possible to draw the same effects as the on/off valves 165 and 175 explained in the first embodiment.

Fourth Embodiment

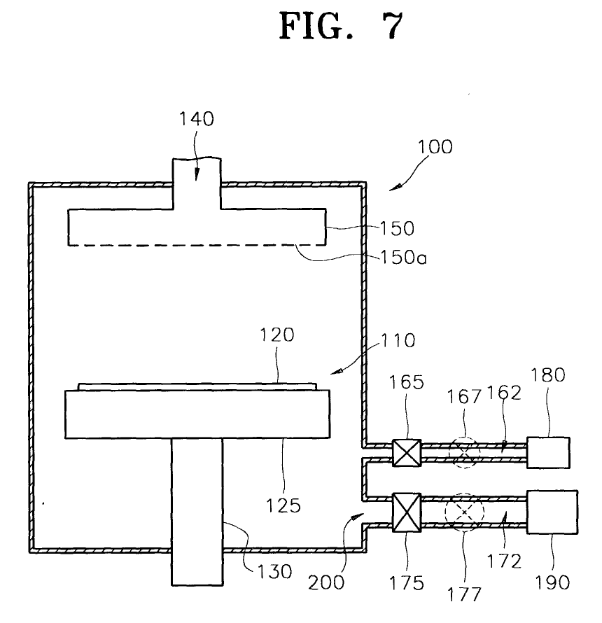

FIG. 7 is a cross-sectional view of the ALD apparatus of FIG. 5. Components that are the same as those used in FIGS. 5 and 6 are described with the same reference numerals and their explanations are omitted.

Referring to FIG. 7, a first outlet 162 through which the process gas is supplied and a second outlet 172 used for purging the process gas do not branch out from one line but rather are formed separately. On/off valves 165 and 175 are installed at the first and second outlets 162 and 172, respectively. The installation of mass flow control valves 167 and 177 is optional. Although the first and second outlets 162 and 172 do not branch out from the same line, their operations are the same as those of the first and second outlets 160 and 170 in FIGS. 2, 5, and 6.

As previously mentioned, in an ALD apparatus according to the present invention, a gas supplying outlet through which particles or remnants are discharged during the supply of process gas and a purging outlet through which a large amount of exhaust gas is discharged during a purging process are installed in a chamber in which an atomic layer is deposited. Accordingly, it is possible to discharge the minimum amount of exhaust gas during the supply of the gas and the maximum amount of exhaust gas during a purging process, thereby maximizing the deposition efficiency.

Further, there is no need to control a pressure control valve every time gas is supplied or purged, and thus, the process can be simplified and smoothly performed.

In addition, an outlet is opened and shut when a gas supply outlet is open during a purging process, thereby preventing fluid turbulence caused by the abrupt opening and shutting of a valve.

What is claimed is:

1. An atomic layer deposition apparatus in which a process gas is repeatedly supplied and purged to deposit an atomic layer, the apparatus comprising:
a chamber for depositing an atomic layer;
a gas injection hole through which a process gas is supplied to the chamber;
a first outlet through which remnants are removed from the chamber when supplying the process gas; and
a second outlet through which exhaust gas is discharged from the chamber when purging the process gas.

2. The apparatus of claim 1, wherein an on/off valve is installed in the first and second outlets, respectively.

3. The apparatus of claim 2, wherein the on/off valve is a slit valve.

4. The apparatus of claim 2, wherein a mass flow control valve, which controls a flow rate of the exhaust gas, is further installed in the first or second outlet.

5. The apparatus of claim 4, wherein the mass flow control valve is a pressure control valve, a butterfly valve, or a throttle valve.

6. The apparatus of claim 1, wherein the first and second outlets branch out from one unified line.

7. The apparatus of claim 6, wherein an on/off valve is installed in the first and second outlets, respectively.

8. The apparatus of claim 7, wherein the on/off valve is a slit valve.

9. The apparatus of claim 7, wherein a mass flow control valve, which controls a flow rate of the exhaust gas, is further installed in at least one of the first and second outlets.

10. The apparatus of claim 9, wherein the mass flow control valve is a pressure control valve, a butterfly valve, or a throttle valve.

11. The apparatus of claim 1, wherein a diameter of the second outlet is larger than that of the first outlet.

12. The apparatus of claim 6, wherein a diameter of the second outlet is larger than that of the first outlet.

13. The apparatus of claim 6, wherein an interlocking valve, which controls the continuous opening of one outlet and selective opening of the other outlet, is installed in the one unified line from which the first and second outlets branch out.

14. The apparatus of claim 1, wherein a pump is installed in the first and second outlets, respectively.

15. The apparatus of claim 1, wherein a single pump is coupled to the first and second outlets.

16. A method of operating an atomic layer deposition apparatus that includes a gas supply outlet and a purging outlet installed on a wall of a chamber of the apparatus and on/off valves that control the outlets, the method comprising:
(a) placing a semiconductor wafer in the chamber;
(b) supplying a first process gas to the semiconductor wafer while the gas supply outlet is opened and the purging outlet is shut;
(c) opening the purging outlet and purging the first process gas;
(d) shutting the purging outlet and supplying a second process gas; and
(e) opening the purging outlet and performing a purging process on the second process gas.

17. The method of claim 16, wherein the gas supply outlet is kept open in steps (c) through (e).

18. The method of claim 17, wherein the gas supply outlet and the purging outlet comprises mass flow control valves that control a flow rate of an exhaust gas,
wherein the mass flow control valves are opened to discharge a minimum amount of the exhaust gas in steps (b) and (d).

19. The method of claim 17, wherein the gas supply outlet and the purging outlet comprise mass flow control valves that control a flow rate of an exhaust gas,
wherein the mass flow control valves are completely opened to discharge a maximum amount of the exhaust gas in steps (c) and (e).

20. The method of claim 16, wherein steps (b) through (e) are repeated at least once.
